(19) United States
(12) Patent Application Publication
(10) Pub. No.: US 2026/0084846 A1
(43) Pub. Date: Mar. 26, 2026

(54) UNMANNED AERIAL VEHICLE WITH OPTIMIZED ROTOR GEOMETRY, ASYMMETRI ARM CONFIGURATION, AND INTEGRATED STRUCTURAL MEMBERS

(71) Applicant: Richard Joseph MItchell, Tavares, FL (US)

(72) Inventor: Richard Joseph MItchell, Tavares, FL (US)

(21) Appl. No.: 19/403,387

(22) Filed: Nov. 28, 2025

(51) Int. Cl. B64U 30/29; B64U 10/16; B64U 20/20; B64U 20/65; B64U 20/70; B64U 50/19; G06F 30/15

(52) U.S. Cl. CPC B64U 30/29; B64U 10/16; B64U 20/20; B64U 20/65; B64U 20/70; B64U 50/19; G06F 30/15

(57) ABSTRACT

An unmanned aerial vehicle (UAV) and airframe architecture are disclosed. A single-plane embodiment utilizes an asymmetric arm length ratio in the range of 1.35:1 to 1.45:1 (approximately 1.41:1) to arrange eight propulsion units in a compact, non-overlapping configuration to achieve high hover efficiency (FM 0.78). The integrated airframe utilizes structural arms with a non-circular cross-section characterized by parallel flat mounting surfaces and convexly filleted sides with conformal wall thickness to minimize parasitic mass and stress concentration. The arm-to-body junction employs a mechanical impedance mismatch zone to attenuate vibration transmission, which may be achieved by a difference in material properties or by a structural impedance element configured for local stiffness change via reduction, increase, or combination in cross-section, potentially using metal inserts. A quantitative design method for bi-planar UAVs uses an aerodynamic power penalty model to precisely control the trade-off between compactness and efficiency.

### BACKGROUND OF THE INVENTION

### 1. Field of the Invention

The present disclosure relates generally to the field of aeronautical engineering and unmanned aerial vehicles (UAVs). More particularly, the invention pertains to a multi-rotor airframe architecture designed to optimize the critical trade-off between aerodynamic efficiency and physical compactness through geometrically determined asymmetric rotor placement. The invention further relates to integrated structural components, specifically non-circular airframe members featuring conformal wall thicknesses configured for minimizing parasitic mass while maximizing torsional rigidity and vibration damping.

### 2. Description of the Related Art

The widespread adoption of multi-rotor UAVs for demanding commercial and industrial applications has necessitated platforms that strike a complex balance between heavy-lift capacity and ease of transport. Conventional designs generally compel manufacturers to choose between two historically limiting extremes: the “planar” configuration and the “coaxial” configuration.

Planar octocopters, which feature eight rotors arranged in a single horizontal plane, are known for offering high aerodynamic efficiency because each rotor operates largely in undisturbed air. However, to maintain this efficiency and prevent detrimental blade interference, the arms must be lengthy, resulting in a large overall airframe diameter (Relative Diameter 1.52). This substantial footprint complicates transportation and restricts operational utility in spatially constrained environments. Conversely, coaxial (×8) configurations stack rotors vertically, achieving maximum compactness, but this size reduction results in severe aerodynamic inefficiencies. The lower rotor operates within the accelerated, turbulent downwash generated by the upper rotor, leading to efficiency losses often exceeding 20% compared to isolated rotors, which translates to a low Figure of Merit (FM) of approximately 0.70.

Structurally, prior art airframes predominantly utilize round carbon fiber tubes. Integrating electric motors, which typically have flat mounting bases, onto round tubes requires heavy adapter plates or complex saddle clamps. These components inflate the overall mass, increase the part count, and are susceptible to torsional slippage during high-torque events, compromising thrust vector alignment and flight control. Furthermore, alternative non-circular tubes sometimes exhibit non-uniform wall thicknesses, often manufactured by wrapping material around a square mandrel, leading to excess material accumulating at corners. This “dead material” adds parasitic mass without contributing significantly to structural stiffness, resulting in a poor stiffness-to-weight ratio.

Finally, vibration management remains a persistent challenge in UAV design. Conventional rigid frames often transmit high-frequency motor noise directly to sensitive avionics and flight controllers. While traditional solutions involve soft damping materials, introducing such mechanical compliance can degrade flight control precision and stability. Therefore, a need exists for a structural architecture that inherently attenuates vibration through mechanical means without relying solely on compliant dampers, and for a systematic design methodology that allows quantitative optimization of the compactness-efficiency trade-off in a predictable manner.

### BRIEF SUMMARY OF THE INVENTION

The present invention comprises an unmanned aerial vehicle (UAV) and a method for its design that systematically addresses the fundamental trade-off between aerodynamic efficiency and structural compactness, while providing an integrated structure of superior mass efficiency and vibration attenuation.

In a first aspect, the invention provides a multi-rotor apparatus, preferably an octocopter, featuring a radially asymmetric arm configuration. The arm length ratio (L₂/L₁) is selected to be substantially v2:1 (approximately 1.41:1), or more generally in the range of 1.35:1 to 1.45:1, allowing all rotor discs to be densely interleaved in a single common plane without aerodynamic or physical overlap. This arrangement achieves a high Figure of Merit (FM) within a significantly reduced footprint compared to conventional planar designs.

In a second aspect, the invention features an integrated airframe utilizing structural arms with a non-circular cross-section having two parallel flat external surfaces and two opposing convexly filleted sides. The arms feature a conformal wall thickness such that the internal geometry tracks the external curvature, eliminating non-structural mass and maximizing the stiffness-to-weight ratio. The flat surfaces enable direct, adapter-free motor mounting, and the filleted sides reduce stress concentrations, improving fatigue life. The junction between the arm and the central body is specifically configured to create a mechanical impedance mismatch, serving as a structural filter to reflect and attenuate high-frequency vibration energy away from sensitive avionics.

In a third aspect, the invention provides a structural member (arm) designed for passive vibration attenuation comprising a zone of local geometric reduction, or “neck.” This neck is configured as a structural discontinuity along the arm's longitudinal axis, characterized by a reduced cross-sectional area and lower local stiffness and mass. This reduction creates a large, local mechanical impedance mismatch sufficient to reflect and attenuate high-frequency vibration energy generated by the propulsion units, preventing its propagation toward the central body avionics. The necked-down zone may be composed of the same material as the rest of the arm (e.g., carbon fiber) or a different material (e.g., metal) to enhance the impedance change.

In a fourth aspect, the arm-to-body junction includes a mechanical impedance transformer comprising one or more localized segments that change mechanical impedance by geometric and/or material variation. The transformer may be realized as (i) a local decrease in cross-section (“neck-down”), (ii) a local increase in cross-section (“bulge” or “widened neck”), or (iii) a combination thereof. In certain embodiments a double-mismatch is formed by two adjacent segments of different sense (e.g., a neck-down followed by a bulged segment, or vice-versa) to increase vibration reflection and localization near the junction without introducing soft, low-frequency isolators. The mechanical impedance can be implemented using metal inserts, necking down, broadening, or any combination thereof-frequency isolators.

In a fifth aspect, the invention provides a quantitative design methodology for bi-planar multi-rotor UAVs. This method links physical geometry (L₂/L₁) to a measurable performance characteristic (hover-power penalty, P/P₀) by utilizing a corrected geometric derivation for the rotor intersection area (a). This enables a designer to precisely calculate the required arm lengths needed to achieve a target aerodynamic penalty, providing a tunable and predictable trade-off between efficiency and compactness.

In a preferred bi-planar octocopter embodiment the upper plane comprises four rotors on arms aligned to the body axes, and the lower plane comprises four rotors on arms rotated by 45°. Let the upper and lower arm lengths be L₁ and L₂, respectively, and the rotor radius be r. The nearest plan-view center spacing between a rotor in the upper plane and a rotor in the lower plane is:

$$d = \sqrt{{L}_{1}^{2} + {L}_{2}^{2} - 2 {L}_{1} {L}_{2} cos ( 45 ° )} = \sqrt{{L}_{1}^{2} + {L}_{2}^{2} - \sqrt{2} {L}_{1} {L}_{2}} .$$

For two equal discs of radius r separated by d, the per-pair fractional overlap area is:

$$f = \frac{a}{π {r}^{2}} = \frac{2 {r}^{2} {cos}^{- 1} ( d / 2 r ) - ( d / 2 ) \sqrt{4 {r}^{2} - {d}^{2}}}{π {r}^{2}} .$$

Hover power is modeled by a hover-power multiplier:

$$\frac{P}{{P}_{0}} = 1 + β f ,$$

where β is an empirical interaction parameter that is a function of normalized plane spacing (h/D, with D=2r). This framework permits a designer to solve forward from an acceptable power penalty to concrete arm lengths, or solve backward from a target footprint to the implied power penalty, enabling a tunable compactness—efficiency trade.

In a width-minimizing realization for a specified L₂/L₁, setting L₁ and L₂ equalizes axis and diagonal extents, producing an overall tip-to-tip width W=2 (L₂+r) while maintaining symmetric authority on the body axes. With folding propellers, a transport envelope W_{f}=2 (L₂+r_{f}) is obtained, where r_{f} is the folded radial projection of the hub and blade root.

One object of the invention is to provide a multi-rotor UAV apparatus wherein eight propulsion units are disposed in a non-overlapping configuration. This can be achieved in either a single plane with differing arm lengths or in two vertically separated planes where one plane has four equal length arms and the second plane has shorter equal length arms. While both configurations eliminate aerodynamic interference, the bi-planar embodiment offers superior mechanical tolerance characteristics and vibration isolation, preventing the propagation of severe vibrations from one motor to its neighbors.

A further object of the invention is to provide a UAV airframe apparatus that reduces component count, mass, and assembly complexity. The arms of the UAV are constructed from tubing having a specific non-circular cross-section comprising two parallel flat sides and two opposing convexly filleted sides. This profile provides flat surfaces for the direct mounting of propulsion motors without adapter plates, while the filleted sides are specifically engineered to reduce stress concentrations, thereby improving the airframe's durability and damage tolerance compared to simple square or rectangular tubing. The central body of the aircraft is fabricated with correspondingly shaped receptacles that receive the non-circular arms, creating an integrated, robust connection that is substantially free of external load-bearing clamping hardware.

Another object of the invention is to provide a method for designing a multi-rotor UAV, particularly a bi-planar octocopter, wherein a first set of propulsion units is disposed in an upper horizontal plane and a second set is disposed in a lower, vertically separated horizontal plane. The method utilizes a specific, quantitative framework to select asymmetrical arm lengths for the upper and lower rotor planes. These arm lengths are selected in conjunction with the vertical separation distance to precisely predetermine and control the degree of horizontal overlap between the rotor discs. This design method allows an aircraft's characteristics to be optimized along a spectrum between maximum aerodynamic efficiency (zero overlap) and maximum physical compactness (partial overlap). This allows a designer to make a conscious, quantitative choice, for example, accepting a calculable power penalty in exchange for a significant reduction in airframe footprint.

These and other objects, features, and advantages of the present invention will become more apparent from the following detailed description of the preferred embodiments when taken together with the accompanying drawings.

### BRIEF DESCRIPTION OF THE SEVERAL VIEWS OF THE DRAWING

FIG. 1: Top is a top plan view of an unmanned aerial vehicle constructed in accordance with a first embodiment of the present invention, with alternating short and long arms and non-overlapping rotor disc layout in a single plane.

FIG. 2 is a top perspective view of the unmanned aerial vehicle of FIG. 1.

FIG. 3 is a detailed, partially exploded perspective view of the junction between an arm of non-circular cross-section and the central body, illustrating the integrated mounting receptacle.

FIG. 4 is a detailed, partially exploded perspective view of the distal end of an arm of non-circular cross-section, illustrating the direct mounting of a propulsion motor thereto.

FIG. 5 is a top plan view of an alternative embodiment of the invention configured as a hexacopter with asymmetrical arm lengths.

FIG. 6 is a top plan view of a second embodiment of the invention, illustrating a bi-planar arrangement with asymmetrical arm lengths configured to produce partial overlap between upper and lower rotor discs.

FIG. 7 is a side elevation view of the embodiment of FIG. 6, illustrating the vertical separation of the rotor planes and the mounting of rotors both above and below the arms.

FIG. 8 is a cross-sectional view of a preferred embodiment of an arm, illustrating a non-circular profile having parallel flat sides and convexly filleted sides.

FIG. 9 is a detailed, partially exploded perspective view, illustrating the junction between an arm with the cross-section of FIG. 8 and a correspondingly-shaped receptacle in the central body.

FIG. 10 is a graph illustrating the relationship between the normalized vertical separation distance (h/D) and the empirical parameter β for use in the design method of the present invention.

FIG. 11 is a diagram comparing the stress concentrations in a standard square-profile arm versus the preferred convexly filleted arm profile under a typical bending load, as determined by Finite Element Analysis.

FIG. 12 is a detailed, conceptual top plan view illustrating the junction between the arm and the central body, showing a locally reduced cross-section (structural impedance neck) designed for passive vibration attenuation by reflecting vibration energy.

FIG. 12A is a conceptual side-elevation schematic of a double-mismatch SIE comprising a neck-down segment and an adjacent widened segment near the body receptacle.

### DETAILED DESCRIPTION OF THE INVENTION

### I. Single-Plane Asymmetric Configuration Apparatus

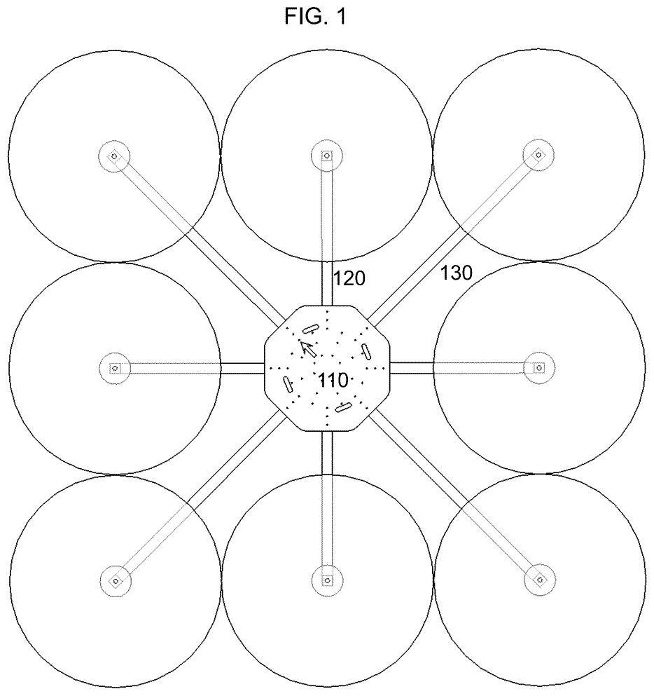

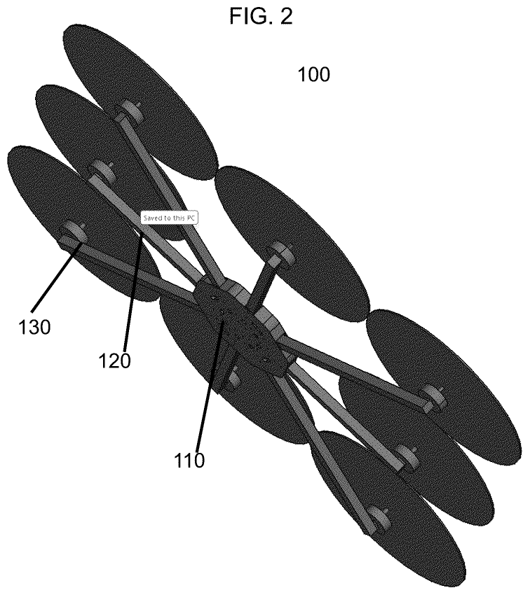

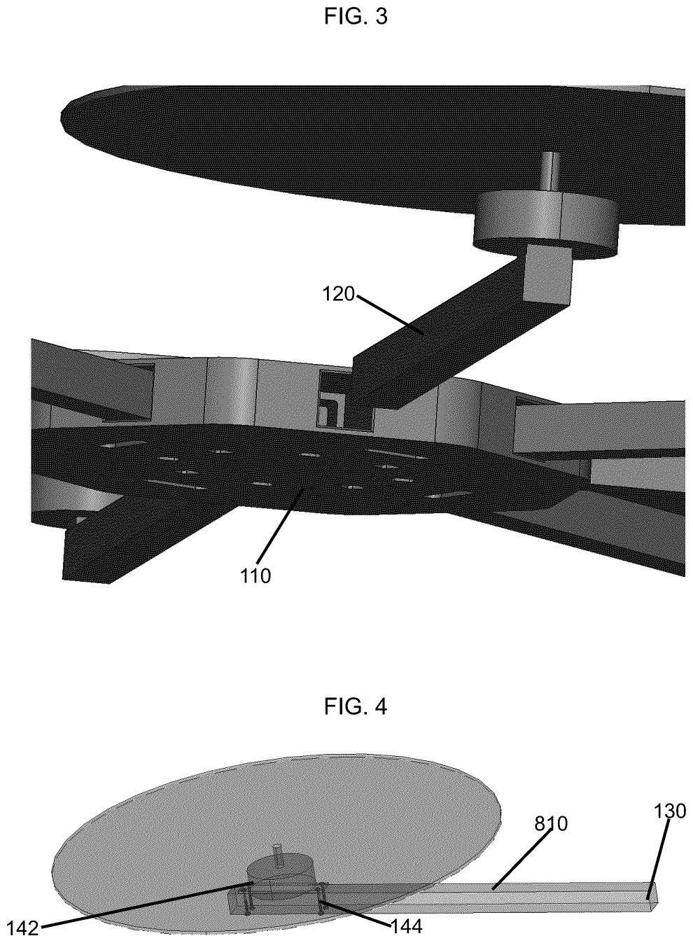

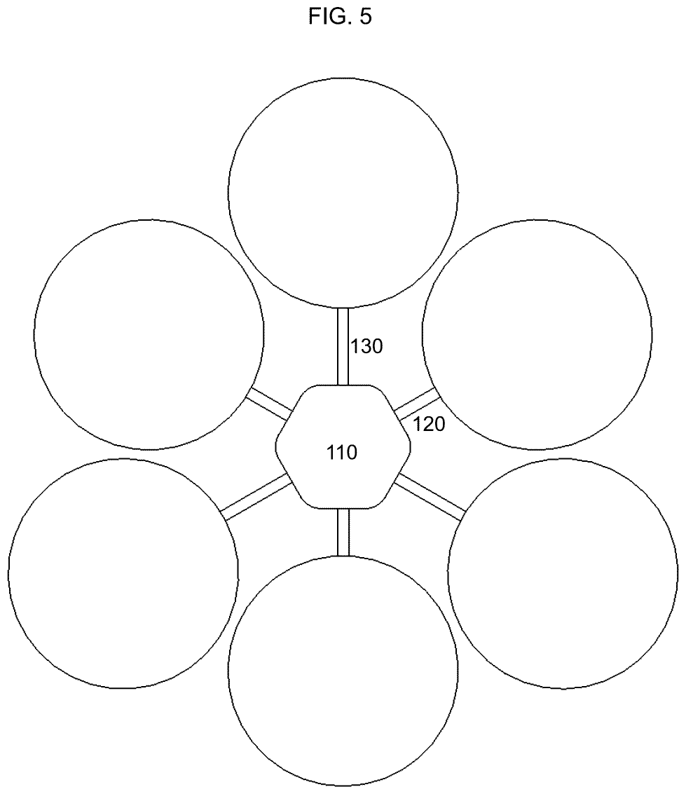

The first embodiment of the UAV (100), illustrated in FIGS. 1 and 2, achieves maximum aerodynamic efficiency in a compact, single-plane octocopter configuration. The central body (110) supports arms divided into a first set (120) of length L₁ and a second set (130) of length L₂, arranged in an alternating sequence.

The effectiveness of this apparatus hinges on a critical geometric feature: the ratio L₂/L₁. The asymmetry is specifically calculated to permit all eight rotors to be disposed in a single horizontal plane without physical or aerodynamic overlap. Through geometric analysis, it has been determined that a ratio of substantially equal to \sqrt{2} (approximately 1.41:1) allows for the dense interleaving of rotor discs in a square grid layout. The preferred operational range that yields this performance benefit is defined as 1.35:1 to 1.45:1. This ensures the rotors on the longer arms (L₂) precisely nestle into the interstitial spaces between the rotors on the shorter arms (L₁), thereby maximizing compactness while maintaining the high efficiency associated with isolated rotors.

Comparative simulations demonstrate the unexpected performance benefit of this fixed asymmetry. The inventive configuration achieves a Figure of Merit (FM) of approximately 0.78, which is nearly identical to the efficiency of the standard planar design (FM 0.78). Crucially, this high efficiency is achieved while maintaining a relative diameter of 1.25, demonstrating significantly greater compactness than the planar design (1.52).

### II. Integrated Airframe Construction and Structural Optimization

### A. Non-Circular Cross-Section and Direct Motor Mounting

A further novel aspect of the invention is an integrated airframe construction designed to reduce component count, weight, and assembly complexity. As illustrated in FIG. 8, the arms utilize a specific non-circular cross-section (800) characterized by two parallel flat sides (810) and two opposing convexly filleted sides (820).

The flat external surfaces (810) provide a direct mounting interface for propulsion units. As shown in FIG. 4, a typical brushless motor (142) with a flat mounting base is secured directly to the arm (130) using fasteners (144). This direct attachment eliminates the need for separate motor mount adapter plates or saddle clamps required by conventional round tubes, reducing weight and part count while simplifying assembly.

### B. Conformal Wall Thickness and Mass Efficiency

The structural arms utilize a construction featuring conformal wall thickness. As depicted in FIG. 8, the internal geometry (805) tracks the external curvature of the cross-section, maintaining a substantially uniform wall thickness throughout.

This topological arrangement eliminates the non-structural “dead material” mass that accumulates at the corners of prior art tubing manufactured with mixed geometries. By ensuring material is placed only where it contributes significantly to structural performance, the inventive profile maximizes the stiffness-to-weight ratio. For the purposes of mass efficiency and structural stability, “substantially conformal” is defined as maintaining a wall thickness variation of no more than 15% across the cross-section.

### C. Structural Integrity and Load Optimization

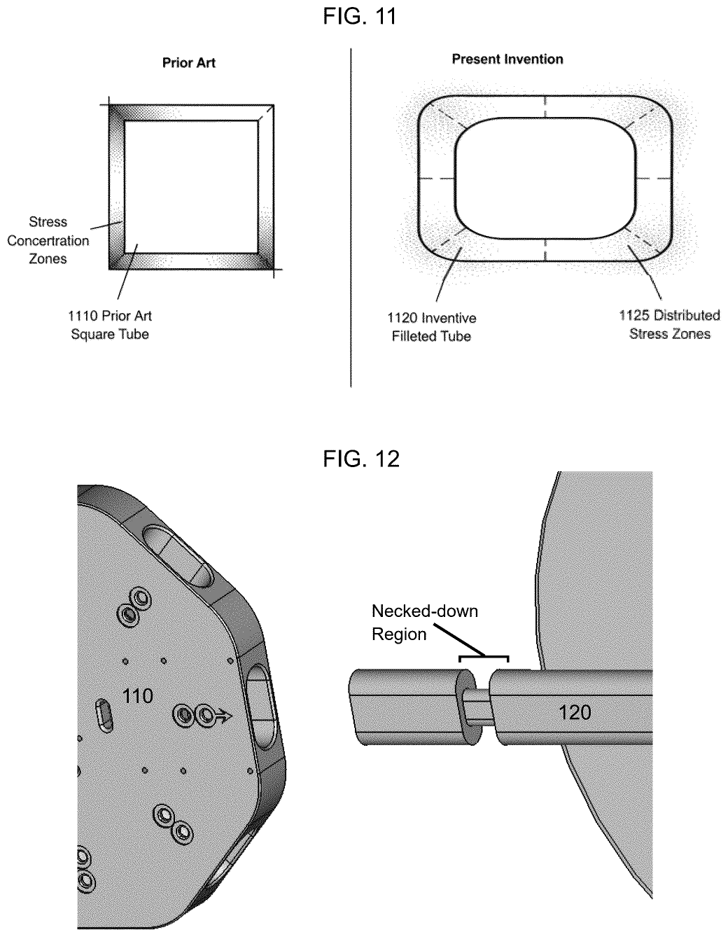

The bi-planar design physically separates the load paths of alternating motors. The specific convexly filleted sides (820) provide a structural advantage over simple square or rectangular tubing. As demonstrated by the Finite Element Analysis (FEA) comparison in FIG. 11, the inventive profile (1120) significantly mitigates stress concentrations (1125) compared to the high stress points (1115) found at the sharp corners of a standard square tube (1110). This reduction in peak stress improves the arm's fatigue life, durability, and damage tolerance, particularly under the high-frequency torsional loads induced by rapid motor acceleration. Furthermore, the rounded leading and trailing edges of the filleted profile reduce the drag coefficient (Ca) by approximately 20% compared to a bluff square tube, benefiting forward flight performance.

For heavy-lift applications, an alternative square hollow section (Design A) is employed, which provides superior structural efficiency and maximum resistance to vertical bending loads by maximizing the Second Moment of Area (I) relative to its mass.

### D. Vibration Management Via Mechanical Impedance Mismatch

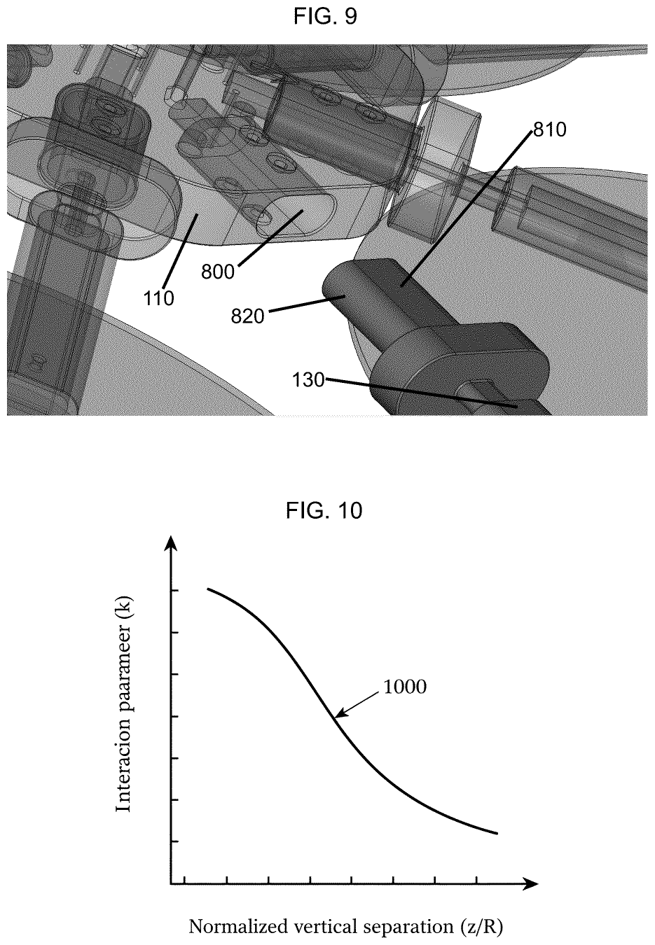

The structural connection between the arm and the central body (FIG. 9) is configured to provide passive vibration isolation. The junction is intentionally designed as a mechanical impedance mismatch zone by selecting materials for the arm and the receptacle that have differing characteristic acoustic impedances (Z). Characteristic acoustic impedance is defined by the relationship Z=\sqrt{Eρ}, where E is the material's elastic modulus and ρ is its density. A sufficient difference in Z between the arm material and the central body material causes the interface to reflect a portion of high-frequency vibration energy, generated by the propulsion units, back into the arm structure. This “structural filter” effectively attenuates the transmission of motor noise and structural resonance frequencies to sensitive avionics located within the central body.

### E. Vibration Management Via a Structural Impedance Element (SIE)

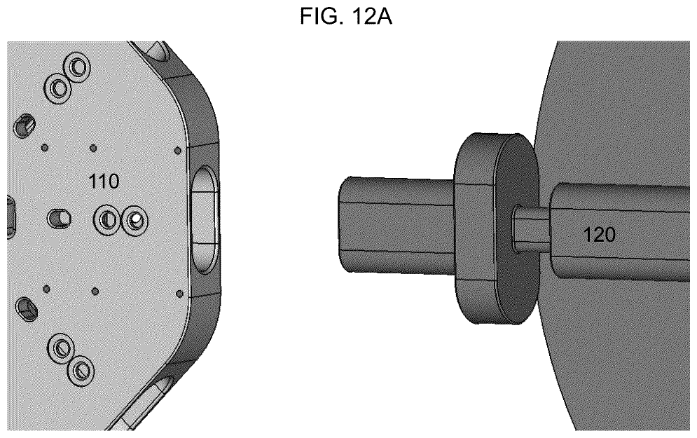

An alternative or supplementary method for passive vibration attenuation is provided by creating a structural impedance element (SIE). The SIE is an axial region of the arm and/or the arm-body interface where mechanical impedance is intentionally altered to reflect and attenuate high-frequency vibration energy propagating from the propulsion units. The SIE may be implemented as a local cross-sectional reduction and/or a local cross-sectional increase in at least one geometric parameter (height, width, wall thickness), and/or by a material change (e.g., insert or sleeve with different elastic modulus and/or density) to produce the desired impedance change. The mechanical impedance can be implemented using metal inserts, necking down, broadening, or any combination thereof. In a double-mismatch embodiment, two impedance steps are placed in close axial proximity (e.g., a neck-down segment adjacent to a widened segment within the body receptacle) to form a compact structural filter. The SIE is dimensioned to remain structurally sound under bending and torsion while maintaining the integrated, non-circular arm-to-body connection described herein. As conceptually illustrated in FIG. 12, the arm or its interface features a zone of local cross-sectional reduction. This reduction is a deliberate structural discontinuity designed to rapidly change the local mechanical impedance (Z) of the arm. And as conceptually illustrated in FIG. 12A, the interference features can consist of an expansion, a reduction, or both in the local cross section.

Mechanical impedance (Z) is a function of the structure's mass (m) and stiffness (k). By locally reducing the cross-sectional area and the Second Moment of Area (I), the structural stiffness of the neck is drastically decreased. This creates a sharp transition from the high-impedance central body and arm structure to a low-impedance neck, causing the majority of the high-frequency vibration energy propagating from the motor to be reflected back into the arm toward the motor.

The interference zone may be fabricated from the same material as the arm (e.g., carbon fiber composite), relying purely on the geometric change to create the required impedance drop. Alternatively, the zone may incorporate a metal section (e.g., Aluminum or Stainless Steel) with a different density and elastic modulus than the main arm material to maximize the total mechanical impedance change (AZ) for enhanced reflection.

The zone geometry must be carefully calculated such that the necked-down zone remains structurally capable of withstanding the peak torsional and bending loads required for flight, acknowledging that the zone is a local stress concentration point.

To design the SIE, the following methodology can be employed. Design targets include: neck flexural stiffness ratio between 0.25 and 0.6; neck area ratio between 0.5 and 0.8. The neck should be kept short compared to the bending-wave quarter-wavelength at the blade-pass frequency (BPF):

$$λ / 4 = \sqrt[4]{( EI / ρ A ) / {( 2 π f )}^{2}} ,$$

targeting Lₙ<<λ/4.

For loads, let T=motor thrust (worst-case per arm); Lₐ=arm length from neck to motor; g=maneuver/failure factor; Q=peak motor/prop drag torque.

For a hollow rectangular tube approximated as thin-walled: Area A=2t (b+h−2t);

Bending inertia I=(bh³−(b−2t) (h−2t)³)/12; Torsion

$$J = 4 {A}_{m}^{2} / {P}_{m} ,$$

with Aₘ median enclosed area and Pin median perimeter.

Stresses: Bending σ_{b}=Mh/2I, with M=TgLₐ; Torsion t=Q/(2Aₘt) (thin-wall closed section). For metals, check von Mises; for composites, ply-level stresses.

Generous transitions: taper≥1:10 (axial:radial) and external fillet radius ≥2t.

### III. Bi-Planar Configurable Architecture and Quantitative Design Methodology

### A. Bi-Planar Advantages (Tolerance and Vibration Decoupling)

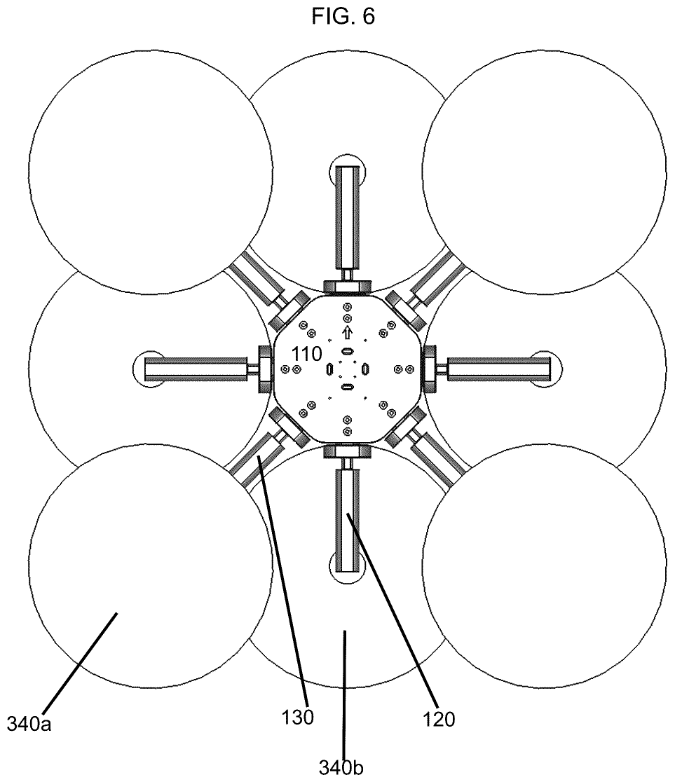

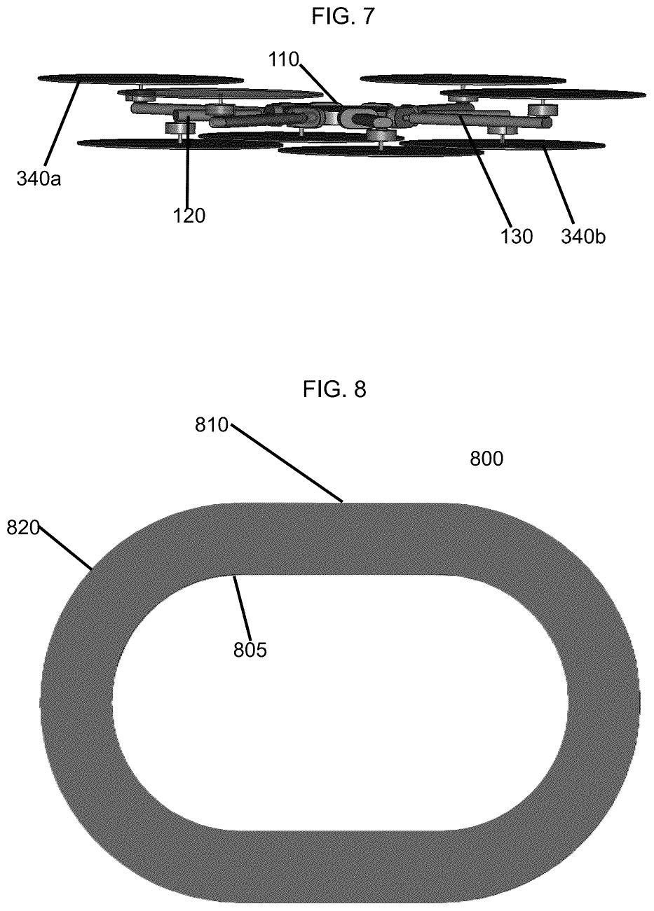

A second preferred embodiment achieves a compact footprint through a bi-planar configuration with a vertical separation (FIGS. 6 and 7). This arrangement offers two distinct mechanical advantages over compact single-plane designs:
1. Relaxation of Mechanical Tolerances: The vertical separation acts as a safety buffer, ensuring that dynamic arm deflection or blade flapping during high-load maneuvers does not result in catastrophic tip strikes, even when the plan-view projection places rotors in close proximity.
2. Vibration Decoupling: The structural impedance changes at the central body junction act to damp and decouple severe vibrations (e.g., from a damaged propeller) originating in one plane, significantly attenuating their transmission to a neighboring motor in the other plane.

The aircraft designed by this method may be further enhanced by mounting the first set of propulsion units (340a) above their respective arms in a “tractor” configuration, and the second set of propulsion units (340b) below their respective arms in a “pusher” configuration.

### B. Quantitative Design Methodology (The Method Claims)

The present invention provides a systematic design methodology that links the bi-planar UAV geometry from a static configuration into a set of tunable design parameters. This method allows designers to quantitatively predict and control the degree of horizontal rotor overlap based on a desired aerodynamic performance characteristic.

The design process begins by defining a target aerodynamic performance For the 45°-staggered layout characteristic, such as a maximum allowable hover-power penalty (P/P₀). The aerodynamic power penalty is modeled using a hover-power multiplier that relates the actual power required (P) to the ideal power for non-overlapping rotors (P₀):

$$\frac{P}{{P}_{0}} = 1 + β f ,$$

Here, f is the fractional overlap area, and B is an empirical interaction parameter determined based on the normalized vertical separation ratio (h/D, where D=2r) by referencing a provided data correlation, such as the curve 1000 shown in FIG. 10. This framework allows a designer to solve backward from the target power penalty to determine the required fractional overlap area (f).

Once the required f is calculated, the design moves to the geometric phase, requiring calculation of the specific plan-view center-to-center spacing (d) necessary to achieve that calculated fractional overlap. The method utilizes a corrected geometric derivation for the area of intersection of two equal circles (a) of radius r where:

$$a = 2 {r}^{2} {cos}^{- 1} ( \frac{d}{2 r} ) - \frac{d}{2} \sqrt{4 {r}^{2} - {d}^{2}} .$$

The fractional overlap is f=a/(πr²). For the 45°-staggered layout (FIG. 6), the plan-view center-to-center spacing is calculated using the Law of Cosines based on the upper arm length L₁ and lower arm length L₂:

$$d = \sqrt{{L}_{1}^{2} + {L}_{2}^{2} - 2 {L}_{1} {L}_{2} cos ( 45 ° )} = \sqrt{{L}_{1}^{2} + {L}_{2}^{2} - \sqrt{2} {L}_{1} {L}_{2}} .$$

The designer then solves for the specific arm lengths L₁ and L₂ that satisfy the required spacing, resulting in an aircraft fabricated with predetermined dimensions guaranteed to achieve the defined balance of performance and compactness.

What is claimed is:

1. An unmanned aerial vehicle (UAV) comprising:
a. a central body;
b. a first set of four arms extending radially from said central body, each arm of said first set having a first fixed length, L₁;
c. a second set of four arms extending radially from said central body, each arm of said second set having a second fixed length, L₂, wherein L₂ is greater than L₁; and
d. eight propulsion units, each propulsion unit mounted to a distal end of one of said first and second sets of arms; wherein said first length and said second length are configured such that the rotor discs of said eight propulsion units are disposed in a single common horizontal plane without overlapping, wherein a ratio of said second length to said first length (L₂/L₁) is in the range of 1.35:1 to 1.45:1 wherein said first and second sets of arms are arranged in an alternating sequence such that rotor discs are interdigitated in a common plane.

2. The UAV of claim 1, wherein said ratio is substantially the square root of 2 (approximately 1.41:1).

3. The UAV of claim 1, wherein said arms are arranged in an alternating sequence of first length and second length around the central body.

4. The UAV of claim 1, wherein said arms are constructed from tubing having a non-circular cross-section having at least one flat surface.

5. The UAV of claim 4, wherein each of said propulsion units comprises a motor having a flat mounting base, said motor mounted directly to said at least one flat surface of one of said arms, thereby eliminating intermediate adapter plates.

6. The UAV of claim 4, wherein said non-circular cross-section comprises two parallel flat sides and two opposing convexly filleted sides.

7. An unmanned aerial vehicle airframe, comprising:
a. a central body defining a plurality of receptacles, each of said receptacles having a non-circular internal geometry;
b. a plurality of arms, each arm constructed from a hollow tube having a non-circular external cross-section comprising two parallel flat opposing surfaces and two opposing convexly filleted surfaces, shaped to be received by one of said receptacles, thereby forming an integrated connection between each said arm and said central body, wherein the integrated connection prevents rotational torque relative to the central body; and
c. a plurality of propulsion units, each propulsion unit comprising a motor having a flat mounting base, wherein each said motor is mounted directly to said at least one flat external surface of one of said arms.

8. The airframe of claim 7, wherein said non-circular external cross-section comprises two parallel flat external surfaces and two opposing convexly filleted sides configured to reduce stress concentrations.

9. The airframe of claim 7, wherein said non-circular external cross-section is substantially square or rectangular and is configured to maximize the second moment of area (I) relative to mass for superior structural efficiency under vertical bending loads.

10. The airframe of claim 7, wherein said arm comprises a hollow tube having an internal cross-sectional geometry wherein said wall thickness varies by no more than 15% across the cross-section to said non-circular external cross-section, thereby maintaining a substantially uniform wall thickness to minimize non-structural mass.

11. The airframe of claim 7, wherein a junction between said arms and said receptacles defines a mechanical impedance mismatch zone, wherein a characteristic acoustic impedance of the arm material differs from a characteristic acoustic impedance of the central body material sufficient to reflect a portion of vibration energy, thereby attenuating vibration transmission to the central body.

12. The airframe of claim 7, wherein said integrated connection is substantially free of external load-bearing clamping hardware configured to structurally secure said arms and resist rotational torque relative to said central body.

13. The airframe of claim 12, wherein said integrated connection is secured by at least one of adhesive bonding and an interference fit.

14. The airframe of claim 7, configured as an octocopter comprising eight of said arms and eight of said propulsion units.

15. The airframe of claim 7, configured as a hexacopter comprising six of said arms and six of said propulsion units.

16. A multi-rotor unmanned aerial vehicle arm comprising:
a. a structural member extending along a longitudinal axis; and
b. a structural impedance element defined along said longitudinal axis, wherein said impedance element comprises a localized change in the arm's cross-sectional properties and/or material relative to adjacent portions of the arm, the element being configured to create a mechanical impedance mismatch sufficient to reflect and attenuate vibration energy propagating along said arm.

17. The arm of claim 16, wherein the localized change is a reduction in cross-sectional area.

18. The arm of claim 16, wherein the localized change is an increase in cross-sectional area.

19. The arm of claim 16, wherein the structural impedance element comprises two or more localized changes arranged axially to form a double-mismatch.

20. The arm of claim 16, wherein the arm is constructed substantially from a composite material, and the change in cross-sectional area of the structural impedance element reduces the local stiffness and mass of the arm, thereby providing the mechanical impedance mismatch.

21. The arm of claim 16, wherein the structural impedance element is located at a junction between the arm and a central body of the UAV.

22. The arm of claim 16, wherein the structural impedance element comprises a material having a different density and elastic modulus than the adjacent arm material to enhance the mechanical impedance mismatch.

23. The arm of claim 22, wherein the adjacent arm material is a carbon fiber composite and the structural impedance element comprises a metallic insert.

24. The arm of claim 16, wherein a ratio of effective mechanical impedance across the element is ≤0.6 or ≥1.6 relative to the adjacent arm section.

25. The arm of claim 16, wherein the axial length of the element is ≤0.25 of a bending-wave quarter-wavelength at a blade-pass frequency of a propulsion unit attached to said arm.

26. A method of designing a bi-planar multi-rotor UAV having a first set of rotors of radius r and diameter D=2r disposed in a first plane and a second set of rotors disposed in a second plane vertically separated from the first plane by a distance h, the method comprising the steps of:
a. defining a target aerodynamic performance limit characterized by a maximum allowable hover-power penalty (P/P₀);
b. determining a value for an empirical interaction parameter β using the predetermined data correlation curve of FIG. 10 based on the normalized vertical separation ratio (h/D) by referencing a provided data correlation;
c. utilizing a quantitative model to calculate a fractional rotor overlap area, f, that corresponds to said predetermined hover-power penalty, wherein said quantitative model relates a hover-power multiplier, P/P₀, to said fractional rotor overlap area by the formula:
$$\frac{P}{{P}_{0}} = 1 + β f ;$$
calculating a required plan-view center spacing (d) between an upper rotor and a lower rotor using an intersection area formula:
$$a = 2 {r}^{2} {cos}^{- 1} ( \frac{d}{2 r} ) - \frac{d}{2} \sqrt{4 {r}^{2} - {d}^{2}} , \qquad f = \frac{a}{π {r}^{2}} ;$$
d. determining a first arm length (L₁) and a second arm length (L₂) that satisfy said spacing for a given stagger angle; and
e. fabricating said unmanned aerial vehicle with said first and second arm lengths.

27. The method of claim 26, wherein the first set of rotors and the second set of rotors are arranged in a 45°-staggered layout, and the center spacing is calculated using the Law of Cosines:
$$d = \sqrt{{L}_{1}^{2} + {L}_{2}^{2} - \sqrt{2} {L}_{1} {L}_{2}} .$$

28. The method of claim 26, wherein said first arm length and said second arm length are calculated to produce a fractional overlap area of substantially zero (f=0) while utilizing the vertical separation distance to provide mechanical clearance for manufacturing tolerances and vibration isolation between adjacent rotors.

29. The method of claim 26, further comprising the step of mounting said first set of rotors above their respective arms in a tractor configuration and mounting said second set of rotors below their respective arms in a pusher configuration.

30. An unmanned aerial vehicle (UAV) airframe, comprising:
a. a central body defining a plurality of receptacles having non-circular internal geometry;
b. a plurality of hollow arms having a non-circular external cross-section comprising two parallel flat external surfaces and two opposing convexly filleted sides, each arm received in a corresponding receptacle to form an integrated connection substantially free of external load-bearing clamping hardware; and
c. a mechanical impedance transformer disposed at or adjacent to a junction of at least one arm and the central body, the mechanical impedance transformer comprising at least one localized segment that changes mechanical impedance by at least one of (i) a geometric change in cross-section and (ii) a material change relative to an adjacent portion of the arm, the transformer being configured to create a mechanical impedance mismatch sufficient to reflect and attenuate vibration energy propagating along the arm toward the central body.

31. The airframe of claim 30, wherein the geometric change comprises a localized increase in cross-sectional dimension relative to the adjacent portion of the arm (a “widened neck” or “bulged” segment).

32. The airframe of claim 30, wherein the geometric change comprises a localized reduction in cross-sectional dimension (a “neck-down” segment).

33. The airframe of claim 30, wherein the mechanical impedance transformer comprises two axially adjacent segments of different sense, one being a localized increase and the other being a localized reduction, thereby forming a double-mismatch structural filter.

34. The airframe of claim 33, wherein the two axially adjacent segments are disposed with a total axial extent less than a predetermined fraction of a bending-wave quarter-wavelength at a blade-pass frequency of a propulsion unit.

35. The airframe of claim 30, wherein the material change comprises an insert or sleeve formed of a material having an elastic modulus and/or density different from that of the adjacent arm material.

36. The airframe of claim 30, wherein the non-circular cross-section maintains a substantially conformal wall thickness.

37. The airframe of claim 30, wherein the integrated connection is secured by adhesive bonding and/or interference fit.
